(19) United States
(12) Patent Application Publication
(10) Pub. No.: US 2006/0001181 A1
(43) Pub. Date: Jan. 5, 2006

(54) Terminal structure of multi-layer substrate and method for forming the same

(75) Inventor: Seok Taek Jun, Kyungki-do (KR)

Correspondence Address: LOWE HAUPTMAN GILMAN AND BERNER, LLP, 1700 DIAGONAL ROAD, SUITE 300 /310, ALEXANDRIA, VA, 22314, US

(73) Assignee: Samsung Electro-Mechanics Co., Ltd., Kyungki-do (KR)

(21) Appl. No.: 11/223,260

(22) Filed: Sep. 12, 2005

Related U.S. Application Data
(62) Division of application No. 10/791,718, filed on Mar. 4, 2004.

(30) Foreign Application Priority Data
Jun. 24, 2003 (KR) 2003-40914

(51) Int. Cl. H01L 29/739

(52) U.S. Cl. 257/913

(57) ABSTRACT

Disclosed is a terminal structure of a multi-layer substrate and a method for forming the same. In the terminal structure, a plurality of terminals are formed on at least two adjacent substrate layers, each of the terminals being spaced from adjacent ones to a predetermined interval. Openings are formed in at least one of the substrate layers. Each of the openings is formed between each adjacent ones of first terminals in the at least one substrate layer, and spaced from the each first terminals to a predetermined gap, and has a size same as that of the first terminals. The substrate layers are stacked one atop another and compressed together so that second terminals formed on at least one corresponding substrate layer are projected to a plane of an outermost substrate layer on which corresponding terminals are formed. The terminal structure and the method can secure a predetermined interval to a plurality of terminals in a package when the terminals are formed as well as simplify formation thereof.

### BACKGROUND OF THE INVENTION

1. Field of the Invention

The present invention relates to a terminal structure of a multi-layer substrate and a method for forming the same, more particularly, which can secure a predetermined interval to a plurality of terminals in a package when the terminals are formed as well as simplify formation thereof.

2. Description of the Related Art

A technique for fabricating a Low Temperature Co-fired Ceramic substrate (hereinafter will be referred to as LTCC substrate) is used to fabricate a Multi-Chip Module (MCM) and a Multi-Chip Package, in which passive elements such as R, L and C for embodying a given circuit are formed on a plurality of green sheets mainly made of glass ceramic via screen printing using a material of excellent electric conductivity such as Ag and Cu, the green sheets are stacked one atop another, and ceramic and metal conductors are co-fired (at a temperature of about 1000° C. or less).

The LTCC technique can co-fire ceramic and metal based upon its process characteristics to advantageously form the passive elements R, L and C inside a module, thereby realizing small-sized thin composite components.

According to the above characteristic ability of forming embedded passives, the LTCC substrate can realize a System-On-Package (SOP) thereby minimizing parasitic effect produced from a Surface Mounted Device (SMD) component. The LTCC substrate also has advantages of improving electric properties owing to reduction of electric noise signals which are produced from soldering regions in surface mounting as well as enhancing reliability owing to reduction of soldered regions. Further, the LTCC technique can adjust coefficient of thermal expansion to minimize Temperature Coefficient of Resonant Frequency Tf, thereby adjusting characteristics of a dielectric resonator.

The LTCC substrate is formed by stacking a plurality of substrate layers having circuits embodied therein. Terminals to be connected with the outside or other chip components are formed outside or inside the package, and electrically connected with an internal circuit pattern.

FIGS. 1a through 1c illustrate outside terminal structures in multi-layer substrates of the prior art. FIGS. 1a and 1b illustrate side elevation views of ceramic packages formed by stacking a plurality of substrate layers one atop another, in which outside terminals 110 are formed on a bottom substrate of a package 100 as shown in FIG. 1a, and lateral outside terminals 120 can be connected with the outside terminals 110. Where the outside terminals 110 are formed on the bottom substrate 150 of the package as above, there is no difference in configuration between the outside terminals 110 of FIGS. 1a and 1b (FIG. 1c).

With the outside terminals 110, as the multi-layer substrate is reduced in size and its components tend to have multiple functions, the interval of the outside terminals is reduced gradually and the size of the outside terminals is reduced also. However, even though a product is gradually reduced in size, the outside terminals are reduced in size only within a limited range in order to ensure reliability to connection between the terminals and an external pattern as well as secure the terminals in the connected position with the external pattern even if any impact is applied thereto.

In inside terminals for being connected with chip components installed within the multi-layer ceramic package, there are tendencies that the interval of the inside terminals is reduced as well as the inside terminals are reduced in size also as in the outside terminals. However, the inside terminals are also reduced in size only within a limited range in order to maintain RF characteristics according to the inside pattern width of the multi-layer substrate.

Therefore, in order to form the outside/inside terminals in the multi-layer substrate which is gradually reduced in size, it is required to gradually reduce the interval of the terminals. However, the interval of the terminals gradually reduced like this creates a problem of electric interference. In currently commercialized package products, the outside terminals have an interval of about 0.3 mm. If a process of forming an interval smaller than 0.3 mm is necessary, this process cannot be performed with existing equipments. There are also several problems in that quality enhancement is required to equipment, the unit cost of products is raised and quality control is difficult.

Therefore the art has required a terminal structure of a multi-layer substrate capable of preventing the foregoing problems.

### SUMMARY OF THE INVENTION

The present invention has been made to solve the foregoing problems and it is therefore an object of the present invention to provide a terminal structure of a multi-layer substrate and a method for forming the same which can reliably secure an interval to terminals in the multi-layer substrate.

It is another object of the invention to provide a terminal structure which can allow a plurality of terminals to be more closed packed and to maintain the interval thereof and prevent short-circuit of the terminals.

According to an aspect of the invention for realizing the object, there is provided a terminal structure of a multi-layer substrate comprising: a plurality of terminals formed on at least two adjacent substrate layers, each of the terminals being spaced from adjacent ones to a predetermined interval; and openings formed in at least one of the substrate layers, each of the openings being formed between each adjacent ones of first terminals in the at least one substrate layer, spaced from the each first terminals to a predetermined gap, and having a size same as that of the first terminals, wherein the substrate layers are stacked one atop another and compressed together so that second terminals formed on at least one corresponding substrate layer are projected to a plane of an outermost substrate layer on which corresponding terminals are formed.

It is preferred that the first and second terminals comprise outside terminals of a multi-layer ceramic package. It is also preferred that the first and second terminals comprise inside terminals for being connected with chip components of a multi-layer ceramic package.

According to another aspect of the invention for realizing the object, there is provided a terminal structure of a multi-layer substrate comprising: a first substrate layer having a plurality of first terminals arrayed on one side thereof, each of the first terminals being spaced from adjacent ones to a first predetermined interval, and openings formed alternating with the first terminals, each of the openings having a size at least same as the terminals and spaced from adjacent ones of the first terminals to a predetermined gap; and a second substrate layer stacked on the other side of the first substrate layer, and having a plurality of second terminals arrayed on one side of the second substrate layer contacting the first substrate layer in positions corresponding to the openings, each of the second terminals being spaced from adjacent ones to a second predetermined interval, wherein the first and second substrates are stacked on each other and compressed together so that the second terminals on the second substrate layer are projected to a plane of the first substrate layer on which the first terminals are formed.

It is preferred that the second terminals have a width which is at least same as that of the first terminals. It is also preferred that the openings are formed via mechanical punching, and the first and second terminals comprise outside terminals of a multi-layer ceramic package.

Preferably, the first and second terminals comprise inside terminals for being connected with chip components of a multi-layer ceramic package.

Preferably also, the second substrate layer comprises at least two sub-layers, and wherein the terminals formed on the first substrate layer and the at least two sub-layers are not overlapped with one another.

According to further another aspect of the invention for realizing the object, there is provided a method for forming terminals in a multi-layer substrate, the method comprising the following steps of:

(a) preparing at least two ceramic layers;

(b) forming terminals on the at least two ceramic layers, each of the terminals being spaced from adjacent ones to a predetermined interval;

(c) forming openings in at least one of the ceramic layers alternating with the terminals, each of the openings being spaced from adjacent ones of the terminals to a predetermined gap and having a size at least same as that of the terminals;

(d) stacking the at least two ceramic substrate layers one atop another and compressing the stacked ceramic substrate layers together; and

(e) firing the stacked ceramic substrate layers.

It is preferred that the step (b) comprises the steps of:

(b1) arraying first ones of the terminals on one side of a first one of the ceramic substrate layers, each of the first terminals being spaced from adjacent ones to a first predetermined interval; and

(b2) arraying second ones of the terminals on at least one second layer of the ceramic substrate layers to be stacked on the first ceramic substrate layer, each of the second terminals being spaced from adjacent ones to a second predetermined interval.

It is preferred that the openings are formed in any of the at least two ceramic substrate layers except for an innermost substrate layer. Preferably, the openings are formed in all of the at least two ceramic substrate layers, and the second terminals have a width at least same as that of the first terminals.

It is preferred that the openings are formed via mechanical punching, and the first and second terminals comprise outside terminals of a multi-layer ceramic package.

It is also preferred that the first and second terminals comprise inside terminals for being connected with chip components of a multi-layer ceramic package.

### BRIEF DESCRIPTION OF THE DRAWINGS

The above and other objects, features and other advantages of the present invention will be more clearly understood from the following detailed description taken in conjunction with the accompanying drawings, in which:

FIGS. 1a through 1c illustrate outside terminal structures in multi-layer substrates of the prior art, in which FIGS. 1a and 1b are side elevation views, and FIG. 1c is a bottom view;

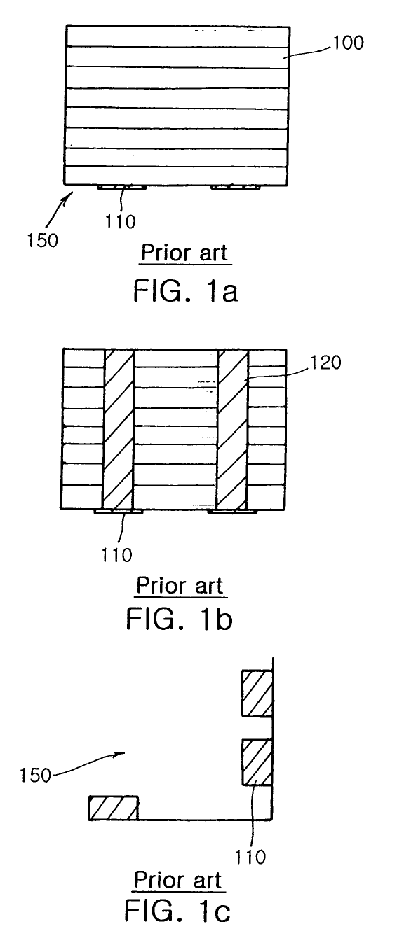

FIG. 2 illustrates process steps of forming outside terminals on substrate layers of a multi-layer substrate according to the invention;

FIG. 3 illustrates a process step of stacking the substrate layers having the outside terminals shown in FIG. 2;

FIG. 4 illustrates a process step of forming openings in the substrate layers shown in FIG. 3;

FIGS. 5a and 5b illustrate process steps of stacking and compressing the substrate layers shown in FIG. 4, in which FIG. 5a shows the substrate layers before being compressed, and FIG. 5b shows the compressed substrate layers;

FIG. 6 is a sectional view illustrating an alternative to the terminal structure of a multi-layer substrate of the invention; and

FIG. 7 is a perspective view illustrating inside terminals of a package adopting the terminal structure of a multi-layer substrate of the invention.

### DETAILED DESCRIPTION OF THE PREFERRED EMBODIMENT

The following detailed description will present preferred embodiments of the invention with reference to the accompanying drawings.

Description will be made first to a method for forming terminals in a multi-layer substrate according to the invention. The method for forming terminals of the invention comprises the following steps of:

a) Forming at least two ceramic layers:

A ceramic green sheet is prepared to form a plurality of ceramic layers, and necessary circuit patterns are formed respectively in ceramic layer areas of the ceramic green sheet, spaced from one another.

b) Forming terminals to at least two ceramic layers to a predetermined interval:

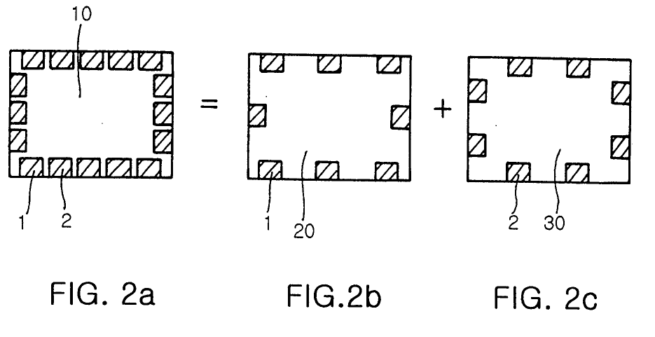

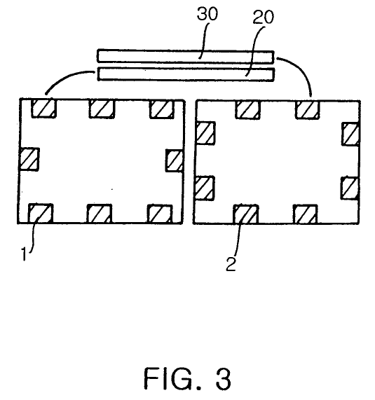

Terminals are separately formed on at least two of the afore-made ceramic layers, each spaced from adjacent ones as shown in FIGS. 2 and 3. That is, a substrate section 10 has a pre-designed outside terminal array (a) which is formed separately on the two substrate layers as shown in FIG. 2. First terminals 1 are formed on a first layer 20 to a first predetermined interval, and second terminals 2 are formed on a second layer 30 to a second predetermined interval, alternating with the first terminals 1.

The pre-designed outside terminal array is formed on the bottom of the substrate section by stacking the substrate layers on each other in which each terminal is spaced from adjacent ones to the predetermined intervals.

This step of separately forming the terminals on the layers is preferably performed in two sub-steps below:

b1) Arraying the first terminals on one side of the first ceramic layer:

The plurality of first terminals 1 are formed on the first layer 20 to the first predetermined interval, in which the first layer indicates a substrate layer having terminals formed thereon according to a conventional technique. The first terminals 1 are so spaced from one another so that the interval between each adjacent ones of the first terminals can receive any terminal sized equal to each of the first terminals.

b2) Arraying the second terminals on at least one second ceramic layer which will be stacked on the first ceramic layer:

After the terminals are formed on the first ceramic layer as in the step b1, the plurality of second terminals are formed on the second layer 30 which will be stacked on the first layer 20, in which each second terminal is spaced from adjacent ones to the second predetermined interval. The second terminals are so arrayed not to overlap with the first terminals 1 on the first layer 20 when the layers are stacked on each other.

While this embodiment adopts a single layer as the second layer, two or more layers can be provided as the second layer. That is, terminals may be formed separately in sequence on three or more adjacent ceramic layers.

c) Forming openings in at least one of the ceramic layers alternating with the terminals, the openings being spaced from the terminals to a predetermined gap and sized at least same as that of each terminal:

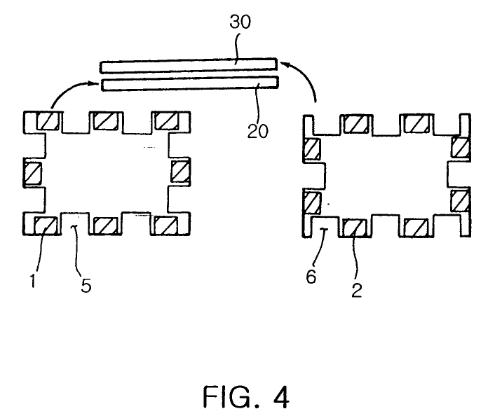

FIG. 4 illustrates a step of forming the openings in the terminal structure of a multi-layer substrate of the invention. In the terminal structure of a multi-layer substrate of the invention, there are provided at least two substrate layers. As shown in FIG. 4, the openings 5 are formed in one of the ceramic substrate layers, that is, the first substrate layer 20.

The openings 5 are formed alternating with the first terminals, and sized equal to or larger than the terminals so that the terminals on the second substrate layer can be projected through the openings 5 up to a plane of the first substrate layer on which the first terminals are formed. Therefore, each of the openings 5 is spaced from adjacent ones of the first terminals 1 on the first substrate layer 20 to the predetermined gap.

According to conventional techniques of forming all terminals in one substrate, an interval of the terminals is narrowed as the terminals are increased in number and the substrate is reduced in size. Then, the narrowed interval disadvantageously causes interference of adjacent terminals. In printing of terminals, it is difficult to prevent a pattern from spreading within a predetermined degree according to resolution. According to factors as above, there has been difficulties for maintaining a narrow gap for example of about 40 μm. As a result, in order to ensure a desired gap to the terminals, the present invention adopts a more precise mechanical process rather than depending on printing precision of the conventional techniques.

The invention forms the above openings with a punching machine. That is, the invention perforates holes in a ceramic green sheets, which the terminals will be formed on, with a tool shaped as the openings to be formed in the ceramic green sheet. This process ensures that the terminals maintain a more precise interval than the conventional techniques which only depend on printing precision.

In the meantime, the second substrate layer 30 may also have openings 6. The openings 6 are also formed alternating with the second terminals 2 on the second substrate layer 30. The openings 5 and 6 help the substrate layers 20 and 30 have generally uniform thickness when the first and second ceramic substrate layers 20 and 30 are stacked on each other and compressed together. The openings 5 and 6 also function to prevent short-circuit in patterns formed in the substrate layers 20 and 30.

d) Compressing the at least two ceramic substrate layers stacked on each other:

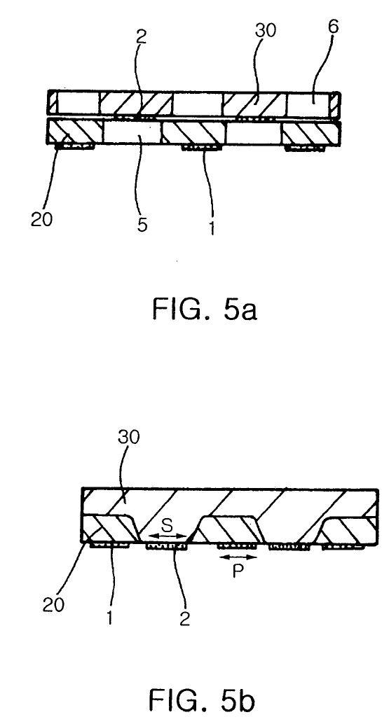

FIGS. 5a and b illustrate a step of stacking and compressing the substrate layers shown in FIG. 4 into a multi-layer substrate, in which FIG. 5a shows the substrate layers before being compressed, and FIG. 5b shows the compressed multi-layer substrate.

The second substrate 30 having the terminals 2 and the openings 6 are stacked on the first substrate 20 having the terminals 1 and the openings 5 so that the second terminals 2 alternate with the first terminals 1. The second terminals 2 are placed above the openings 5 of the first substrate layer 20.

Then, the substrate layers 20 and 30 are simultaneously compressed so that the first and second terminals 1 and 2 on the first and second substrate layers 20 and 30 are formed on a same plane. That is, the second terminals 2 on the second substrate layer 30 are extended downward through the openings 5 of the first substrate layer 20 to fill the openings 5 as shown in FIG. 5b while descending to the same plane as the first terminals 1. In this case, the terminals have a predetermined interval same as the gap between the openings 5 and the first terminals 1.

This ensures a more precise interval to the first and second terminals 1 and 2 than the conventional techniques of simultaneously printing the first and second terminals. At the same time, the first and second terminals 1 and 2 can be arrayed more closely than in the conventional techniques.

e) Co-firing the stacked multi-layer ceramic substrate:

The multi-layer ceramic substrate embodied according to the above steps is co-fired to form a single package.

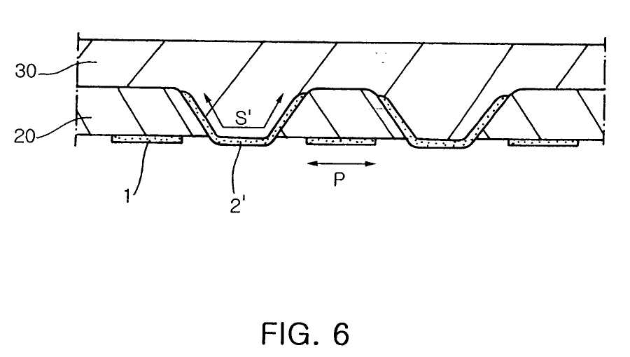

FIG. 5b illustrates the terminal structure of a multi-layer substrate embodied according to the above terminal forming steps, and FIG. 6 illustrates an alternative to the terminal structure of a multi-layer substrate of the invention.

In FIG. 5b, the width S of the second terminals 2 is same as the width P of the first terminals 1, in which the second terminals 2 do not overlap with the openings 5 of the first substrate 20 since the width S of the second terminals 2 is smaller than the width of the openings 5 of the first substrate 20. In FIG. 6, however, second terminals 2′ of a second substrate layer 30 has a width S′ formed larger than the width P of first terminals 1 so that the second terminals 2′ are bent into the multi-layer substrate while butting on boundaries of openings 5 of a first substrate layer 20.

Forming the second terminals 2′ as shown in FIG. 6 ensures that the second terminals 2′ are protruded through areas of the openings 5 from the bottom of the multi-layer substrate so that process reliability can be advantageously enhanced.

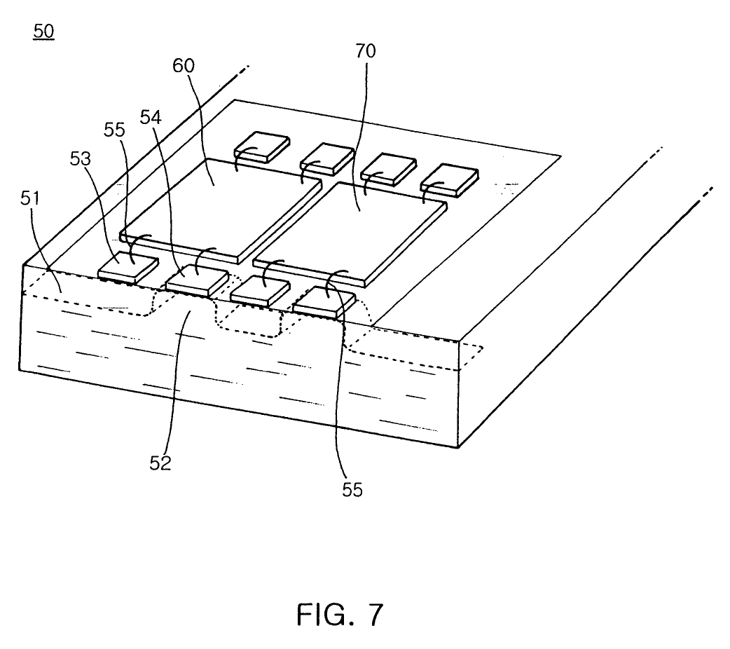

The afore-described embodiments illustrate the outside terminal structures formed in the multi-layer ceramic package. The terminal structures of the invention can be applied to formation of inside terminals in the package. FIG. 7 is a perspective view illustrating inside terminals of a package 50 adopting the terminal structure of a multi-layer substrate of the invention.

The terminal structure in FIG. 7 is same as the terminal structures in FIGS. 5b and 6 in an overturned position. In FIG. 7, a first substrate layer 51 is stacked on a second substrate layer 52, and first terminals 53 are arrayed on the first substrate layer 51 to a first predetermined interval. Openings are formed in the first substrate layer 51, with each of the openings being placed between two adjacent ones of the first terminals 53. Second terminals 54 are formed on the second substrate layer 52 to a second predetermined interval, and projected through the openings while filling hollow spaces of the openings. The inside terminals formed as above are electrically connected via wires 55 with chip elements 60 and 70 such as a Surface Acoustic Wave (SAW) filter.

Each of the afore-described terminal structures is formed by stacking at least two substrate layers one atop another, and compressing the substrate layers together at terminal portions thereof. However, terminal portions of the multi-layer substrate formed to a thickness different from other portions of the substrate do not create any surface irregularity or internal irregularity to the substrate because a plurality of other substrate layers are further stacked on or under the substrate in addition to the above substrate layers and each substrate layer is thin.

According to the present invention as set forth above, although reducing the size of the components and/or the substrate causes reduction to the interval of the outside or inside terminals, the terminals are separately printed on the substrate layers and then the substrate layers are stacked one atop another to place the terminals on a single plane so as to prevent problems such as defects and interval reduction which may occur in the outside terminals owing to printing.

Further, the present invention forms the gap of the terminals by removing predetermined regions of non-printed areas each placed between two adjacent ones of the outside terminals through mechanical process so that the gap can be made uniform and precise and the area of the outside terminals can be uniformly formed at a predetermined size.

Moreover, the present invention can prevent short-circuit of the terminals which may occur in printing.

Although the preferred embodiments of the present invention have been disclosed for illustrative purposes, those skilled in the art will appreciate that various modifications, additions and substitutions can be made without departing from the scope and spirit of the invention as defined in the accompanying claims.

1-4. (canceled)

5. A method for forming terminals in a multi-layer substrate, the method comprising the following steps of:
(a) preparing at least two ceramic layers;
(b) forming terminals on the at least two ceramic layers, each of the terminals being spaced from adjacent ones to a predetermined interval;
(c) forming openings in at least one of the ceramic layers alternating with the terminals, each of the openings being spaced from adjacent ones of the terminals to a predetermined gap and having a size at least same as that of the terminals;
(d) stacking the at least two ceramic substrate layers one atop another and compressing the stacked ceramic substrate layers together; and
(e) firing the stacked ceramic substrate layers.

6. The method for forming terminals in a multi-layer substrate as set forth in claim 5, wherein the step (b) comprises:
(b1) arraying first ones of the terminals on one side of a first one of the ceramic substrate layers, each of the first terminals being spaced from adjacent ones to a first predetermined interval; and
(b2) arraying second ones of the terminals on at least one second layer of the ceramic substrate layers to be stacked on the first ceramic substrate layer, each of the second terminals being spaced from adjacent ones to a second predetermined interval.

7. The method for forming terminals in a multi-layer substrate as set forth in claim 5, wherein the openings are formed in any of the at least two ceramic substrate layers except for an innermost substrate layer.

8. The method for forming terminals in a multi-layer substrate as set forth in claim 5, wherein the openings are formed in all of the at least two ceramic substrate layers.

9. The method for forming terminals in a multi-layer substrate as set forth in claim 5, wherein the second terminals have a width at least same as that of the first terminals.
